(19) United States
(12) Patent Application Publication
(10) Pub. No.: US 2023/0360887 A1
(43) Pub. Date: Nov. 9, 2023

(54) MAINTENANCE FOR REMOTE PLASMA SOURCES

(71) Applicant: Advanced Energy Industries, Inc., Denver, CO (US)

(72) Inventors: Scott Polak, Fort Collins, CO (US); Jeffrey Harrell, Fort Collins, CO (US); David W. Madsen, Fort Collins, CO (US); Andrew Shabalin, Fort Collins, CO (US)

(21) Appl. No.: 18/112,971

(22) Filed: Feb. 22, 2023

Related U.S. Application Data
(63) Continuation of application No. 16/276,320, filed on Feb. 14, 2019, now abandoned.

(51) Int. Cl. H01J 37/32

(52) U.S. Cl. CPC H01J 37/32357; H01J 37/32366

(57) ABSTRACT

A system and method for optimizing maintenance of a remote plasma source comprises recording data from a remote plasma source. The data comprises measurements of one or more operating characteristics of the remote plasma source over a period of time and a plurality of indications of system fault event. The method may include receiving the data; analyzing the data; and determining, based on correlations between the measurements of the one or more operating characteristics and the plurality of system fault events, a threshold of an operating point. The operating point may comprise the measurements of the one or more operating characteristics at a particular time. The threshold signifies a pending system fault event is probable to a defined degree of confidence within a specified window of time. The system provides a notification to perform preventative maintenance on the remote plasma source.

### CLAIM OF PRIORITY UNDER 35 USC 120

The present application for patent is a Continuation of pending U.S. patent application Ser. No. 16/276,320 entitled MAINTENANCE FOR REMOTE PLASMA SOURCES, filed Feb. 14, 2019, which is assigned to the assignee hereof and hereby expressly incorporated by reference herein.

### BACKGROUND

In the semiconductor and thin-films industries, remote plasma sources (RPS) are used in many applications to generate a plasma remote from a primary processing chamber in which the semi-conductor or thin film device is fabricated. Multiple mechanisms within a plasma can degrade the RPS chamber walls: for example, kinetic bombardment of positively charged ions can physically heat and sputter away material from the chamber walls. Additionally, surface reactions may remove material, add material, and/or modify the chemistry of the chamber walls. As the RPS chamber walls degrade, preventative maintenance is required to clean or resurface and/or replace the chamber walls.

In current approaches, preventative maintenance on an RPS is administered at regular intervals so it will continue to provide the required performance. Removing an RPS for preventative maintenance can result in sometimes significant expense, so there is desire to maximize time between preventative maintenance intervals. However, if preventative maintenance intervals are too far apart, the risk of degradation to the point where service is required increase, which is often more costly than preventative maintenance. Current approaches for timing preventative maintenance are not optimized. There is therefore a need in the art for ways to optimize the time between preventative maintenance events.

### SUMMARY

An aspect of the present disclosure provides a system for optimizing remote plasma source maintenance. The system may comprise a remote plasma source and a data acquisition device connected to the remote plasma source and configured to record data. The data may comprise measurements of one or more operating characteristics of the remote plasma source over a period of time and a plurality of indications of system fault events. The system may further comprise a computing device configured to receive the data from the data acquisition device, analyze the data, and determine, based on correlations between the measurements of the one or more operating characteristics and the plurality of system fault events, a threshold of an operating point, the operating point comprising the measurements of the one or more operating characteristics at a particular time, wherein the threshold signifies a pending system fault event is probable to a defined degree of confidence within a specified window of time. The system may provide a notification to perform preventative maintenance on the remote plasma source.

Another aspect of the disclosure provides a method for optimizing maintenance of a remote plasma source. The method may comprise recording data from a remote plasma source. The data may comprise measurements of one or more operating characteristics of the remote plasma source over a period of time and a plurality of indications of system fault events. The method may include receiving the data; analyzing the data; and determining, based on correlations between the measurements of the one or more operating characteristics and the plurality of system fault events, a threshold of an operating point. The operating point may comprise the measurements of the one or more operating characteristics at a particular time. The threshold may signify a pending system fault event is probable to a defined degree of confidence within a specified window of time. The method may comprise providing a notification to perform preventative maintenance on the remote plasma source.

Yet another aspect of the disclosure provides a non-transitory, tangible computer readable storage medium, encoded with processor readable instructions to perform a method for optimizing maintenance of a remote plasma source. The method may comprise recording data from a remote plasma source. The data may comprise measurements of one or more operating characteristics of the remote plasma source over a period of time and a plurality of indications of system fault events. The method may include receiving the data; analyzing the data; and determining, based on correlations between the measurements of the one or more operating characteristics and the plurality of system fault events, a threshold of an operating point. The operating point may comprise the measurements of the one or more operating characteristics at a particular time. The threshold may signify a pending system fault event is probable to a defined degree of confidence within a specified window of time. The method may comprise providing a notification to perform preventative maintenance on the remote plasma source.

### BRIEF DESCRIPTION OF THE DRAWINGS

FIG. 1 is a block diagram illustrating a remote plasma source upstream of a plasma processing chamber within a system of the present disclosure.

FIG. 2 is a block diagram illustrating a remote plasma source downstream of a plasma processing chamber within a system of the present disclosure.

FIG. 3A depicts data comprising operating characteristics used for creating predictive analytics according to the present disclosure.

FIG. 3B depicts raw and filtered data measuring a parameter that increases over time in relation to a threshold and a system fault event.

FIG. 3C depicts raw and filtered data measuring a parameter that decreases over time in relation to a threshold and a system fault event.

FIG. 4 shows an N-dimensional parameter space divided by a hyperplane with a nominal dimension of N−1.

FIG. 5 is a network architecture diagram depicting components of a predictive analytics system of the present disclosure.

FIG. 6 is a flowchart depicting a method of the present disclosure.

FIG. 7 is a logical block diagram of a computing device that may be used to implement aspects of the present disclosure.

### DETAILED DESCRIPTION

The word “exemplary” is used herein to mean “serving as an example, instance, or illustration.” Any embodiment described herein as “exemplary” is not necessarily to be construed as preferred or advantageous over other embodiments.

Numerous industrial applications use remote plasma sources (RPS) in manufacturing of semiconductors, thin-film devices, and other products made with plasma processing chambers. Such applications typically involve one or more RPS positioned upstream or downstream in the manufacturing process of the plasma processing chamber (the “primary processing chamber”) in which the product is being fabricated. Applications include using an RPS to generate Fluorine or Oxygen radicals upstream of the processing chamber, which are used to clean the chamber between processes. FIG. 1 shows a simple block diagram of a plasma processing system 100 having a gas source 130 and an RPS 150 upstream of a primary processing chamber 120. As will be described more thoroughly through the disclosure, the RPS 150 is connected to a data acquisition system (or “data acquisition device”) 180. The data acquisition system 180 may be connected to one or more computing devices, including computing device 185, which may be local, and/or a remote computing device (e.g., a remote cloud server) 190. Another application is the use of an RPS 150 upstream of the processing chamber to deliver a stream of low-energy, neutral, radicals to perform a gentle surface modification of a delicate wafer such as a semiconductor layer.

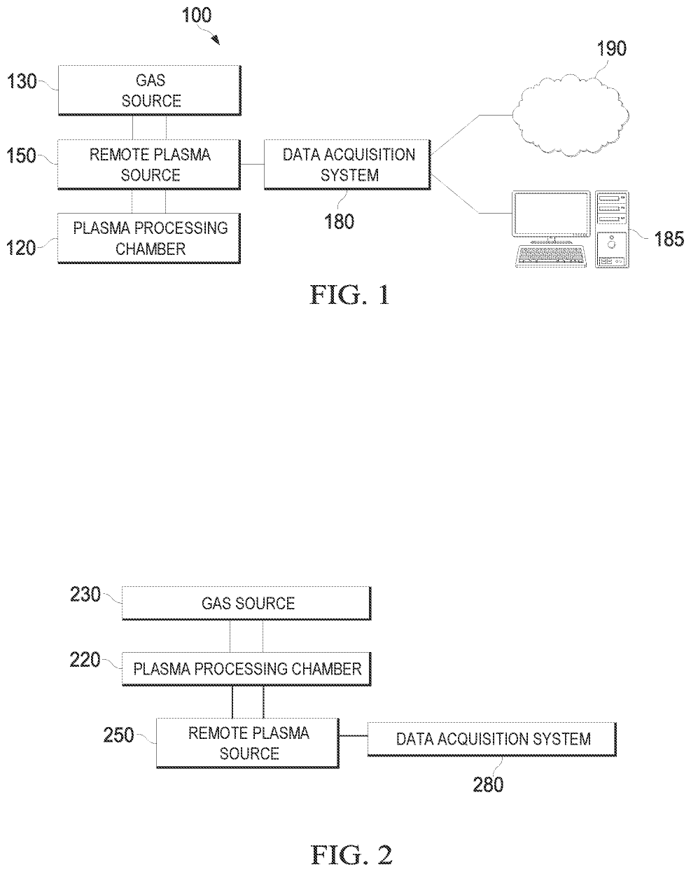

Yet another application is the use of an RPS for plasma-based abatement downstream of processing chamber, to reduce the global warming potential of the effluent gases. For example, some primary plasma processing chambers use, as a result of a semiconductor creation process, gases with high greenhouse warming potential such as NF₃, CF₄, and SF₆. Abatement of these gases is desirable to transform them into gases or other byproducts with far less greenhouse warming potential. In such cases, a downstream RPS such as RPS 250, shown in FIG. 2 may be used. In some cases, an abatement catalyst fluid (gas, in some cases produced by evaporating fluid) may be added to the effluent of the processing chamber, upstream of the RPS 250. In such applications, therefore, an additional “gas source” may feed into the RPS 250. The RPS 250 may comprise a linear or toroidal chamber with an electromagnetic coil used to create a plasma. This may be implemented by various RPS types manufactured by Advanced Energy Industries of Fort Collins, Colorado. As shown in FIG. 2, the RPS 250 is also connected to a data acquisition system 280. Though not shown, the data acquisition system 280 may be connected to a local and/or cloud computer similar to those shown in FIG. 1.

In each of these RPS applications, various mechanisms can cause either unwanted material to be deposited on the walls of the RPS or unwanted removal of material from the walls. In the case of unwanted material being deposited, these contaminants may include powdery substances such as sulfur oxides, which physically build up and form layers on the walls of the RPS plasma chamber. In the case of unwanted removal of material from walls, this may be caused by ions in the plasma bombarding the walls, eroding them away. This mechanism of degradation may be referred to herein as “sputtering away” material from the side walls. Some RPS systems are designed to provide an inductively coupled plasma (ICP) as the primary mechanism of coupling energy into the plasma; however, due to the inherent electric potentials and resulting, stray, electric fields that form in these designs, some degree of capacitively coupled plasma (CCP) may also exist. The ratio of capacitive to inductive coupling in such systems can vary with pressure and power, usually with a greater amount of capacitive coupling existing at higher gas pressure and/or lower power levels. Certain applications require the plasma to operate under conditions of higher degrees of capacitive coupling; in such conditions, the ions are accelerated to the wall with greater energy compared to a purely ICP plasma, resulting in an increased sputtering rate of the chamber wall. In some cases, this sputtering erosion may appear to cause warping or uneven wear of the walls, because the ions bombard and erode the walls in patterns corresponding to the coil around the RPS; that is, where the electric field is concentrated.

Preventative maintenance can comprise either cleaning or resurfacing the inside of the walls, or removing and replacing the walls. Preventative maintenance can be time consuming, and when the maintenance requires replacement, can be costly. It is therefore desirable to maximize the time between preventative maintenance events.

However, preventative maintenance is more desirable than events that trigger system faults. A “system fault,” as defined in this disclosure, is any event significant enough to require some kind of corrective maintenance, such as unplanned cleaning, refurbishment, or replacement of RPS components. A system fault event can include failure of the RPS to ignite a plasma, failure of operation of the RPS, or significant performance deterioration in one or more aspects of the RPS's application functions. System fault events requiring unplanned cleaning, refurbishment, or replacement may be significantly more costly, both in time and money, than preventative maintenance. A system fault event can be extremely problematic when it occurs unexpectedly, because an RPS is typically part of a larger manufacturing process of highly sensitive and costly products.

RPS units can report real-time operating characteristics, such as voltage, current, phase between the AC voltage and current driving at the coil or electrode, temperature, impedance, and other measurements. In other words, it may be equipped with multiple measurement output mechanisms for such characteristics, because these characteristics may be used for interacting with the plasma processing system to which it is connected. For example, they can be used to regulate generated power from a connected RF generator. However, this data is often only collected if a log file is manually initiated by a user connected to the RPS device. In embodiments of the present disclosure, an RPS may be outfitted with a data acquisition system, the data acquisition system configured to record multiple real-time operating characteristics of the RPS. It is contemplated that any type of measurable output from an RPS may be measured and recorded by the data acquisition system, such as the voltage, current (either DC or AC), temperature, and impedance described above. Temperature, in particular, may be measured at multiple sensors, including thermistors and thermocouples, at different places throughout the RPS. Long-term monitoring of temperature may be especially important in generating the predictive analytics of the present disclosure, because initial operating temperatures for different systems, even those created by the same manufacturer, can have high variability due to variations in slope and offset in the temperature sensors at the time of manufacture.

It is also contemplated that the data acquisition system may record other measurable output from components of the plasma processing system to which an RPS is connected. For example, in some applications, plasma processing is used in conjunction with cooling water systems. In order to maximize the efficiency of such systems, measurements of flow rate, inlet and outlet temperatures, and water pressure may be taken or calculated. In some applications, characteristics of gas utilized within the plasma processing systems may be measured. These include gas flow rates, gas pressures inside chambers, and actual compositions of gasses.

As previously described, the data acquisition system, in many embodiments, is configured to be connected to one or more computing devices and/or a network, and to send its recorded data thereto. The data acquisition system and the network components to which it is connected may be referred to as the “predictive analytics system” of the present disclosure. It is contemplated that the data acquisition system may collect, record, and send any measurable operating characteristics, and that a predictive analytics component of the system, implemented at a computing device, may calculate measurement parameters based thereon. These calculated measurement parameters (also referred to herein as “indirectly derived” parameters” may include a variety of measurements, depending on the configuration of the RPS; some examples of these indirectly derived parameters may be: chamber wall thickness, chamber reactance, or plasma and chamber impedance. However, calculated measurement parameters may include any metric that is not directly measured, but is rather derived from other directly measured characteristics. Another possible measurement is the degree of capacitive coupling compared to inductive coupling. Many plasma processing applications are intended to work through inductive coupling processes. However, in certain applications, the physics of the plasma is such that capacitive coupling can become dominant, which may be undesirable for several reasons, including that capacitive coupling may increase the rate of material buildup upon, or material sputtering from, the RPS walls. Material may be removed or deposited depending on gas chemistry and pressure.

In some embodiments, certain operating parameters which are not directly measured may be estimated (i.e., by calculations) from other directly measured operating characteristics. These may include the phase of the power delivery waveform, and the capacitance or thickness of the walls of the RPS itself. In other embodiments, these calculated measures may be directly measured.

In embodiments of the disclosure, the data acquisition system may record operating characteristics of a particular RPS in a particular application over time. For example, one data acquisition system may be locally connected (e.g., through a short cable, or on a local area network (LAN)) to an RPS for generating Fluorine or Oxygen radicals. The operating characteristics of this particular RPS may be collected over time and analyzed by a connected computing device in relation to the occurrence of preventative maintenance events and system fault events. Based on patterns of correlation between particular measurements and the system fault events, the computing device may, over time, create models of these operating characteristics that show when a system fault event is likely to occur. In certain applications, it is known that preventative maintenance should be performed at least every few days, and in others, every few weeks. Given that operators of RPS likely want to avoid system fault events altogether, it may take a very long time to collect sufficient data to create an accurate model from a single RPS for a single application.

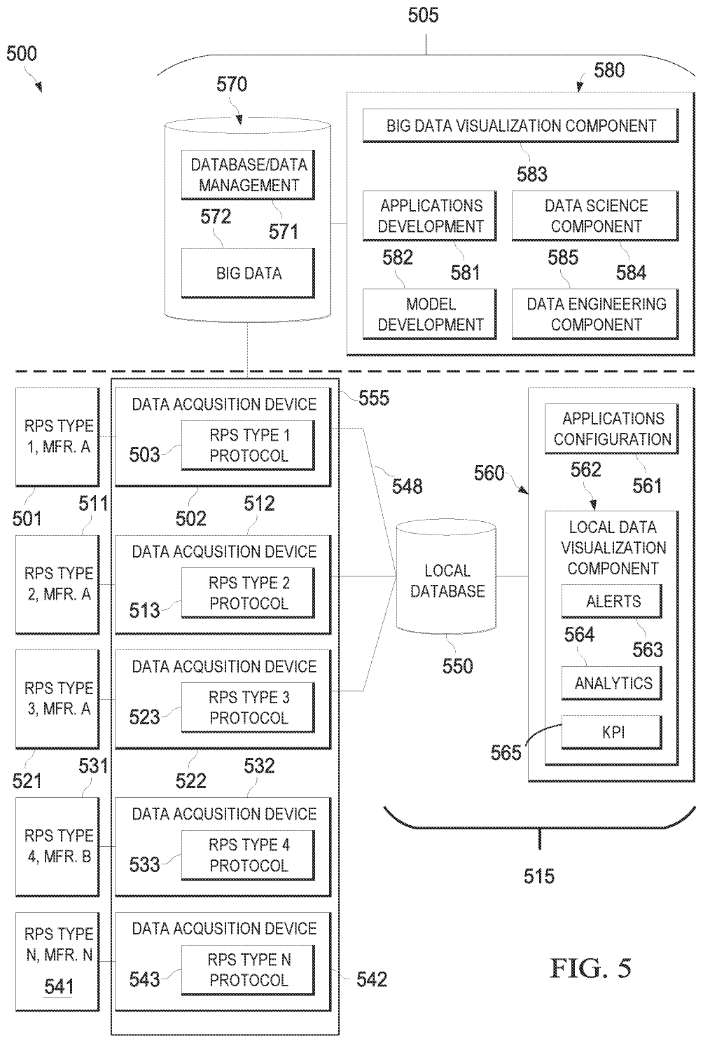

However, the more data can be collected about a particular type of RPS used in a particular application, the more quickly and accurately predictions may be made. If, for example, a single manufacturer of thin films uses dozens of such RPS for generating Fluorine or Oxygen radicals, the connected data acquisition systems may collect many more instances of preventive maintenance and system fault events in a shorter period of time. In embodiments of the present disclosure, such operating characteristics may be collected from users (e.g., manufacturers) in multiple remote locations, and users may each have multiple RPS units. Data on operating characteristics from each of these RPS units may be collected by their respective data acquisition systems and sent to a centralized server or cloud server, as will be described in detail with reference to FIG. 5. The server may implement the predictive analytics system to create more accurate models to predict what types of measured operating characteristics correlate with system fault events, which allows the system to create alerts or recommendations on when to perform preventative maintenance.

Over time, the amount of data collected and analyzed about a particular type of RPS in a particular application may become so robust that the predictive analytics become accurate to a desired degree of confidence; that is, the system may calculate a numerical probability of greater than a particular threshold (e.g., 95%) that a system fault event will occur within a certain predefined time period (e.g. 12 hours). In such cases, it is contemplated that RPS for these applications may be used by the data acquisition system with only a local computing device, rather than send the data to a remote server. The data acquisition system and local computing device may be equipped with a built-in algorithm, derived from the large data-gathering system implemented with multiple remote users. This built-in algorithm may then be used to provide preventative maintenance alerts to a local user without the local system being connected to a remote server.

Though highly accurate models may be derived from analyzing big data sets of operating characteristics for a particular type of RPS for a particular application, there are many different kinds of RPS, and they are used for many different applications. Some RPS operating characteristics (i.e., temperature, impedance, voltage) may have extremely high variability from one unit to another. For example, temperature ranges between different units of the same model may be several degrees different (e.g., 5-10 degrees Celsius) depending on manufacturing differences or operating environments.

Differences in operating characteristics between different kinds of RPS may be even more drastic. Inductive coupling and capacitive coupling RPS, for example, may differ in each possible measurement. RPS systems made by different manufacturers for similar applications have differences in operating characteristics as well.

The number of differences between RPS units and the number of different applications for which they may be used create an exponential number of optimized preventative maintenance thresholds and schedules. It is likely that each combination of type of RPS unit and application has its own preventative maintenance schedule that would maximize the time between preventative maintenance events while preventing any system fault events.

The system of the present disclosure provides ways to collect and record data from any combination of RPS and application, analyze it over time, create models of operating characteristics based on the analysis, and implement machine learning to create algorithms that optimize the construction of a preventative maintenance model. A benefit of implementing machine learning to create algorithms is eliminating the need to manually create algorithms for each RPS unit and application combination. As an example of how a machine learning algorithm may create a preventative maintenance schedule, a “reinforcement”-type learning algorithm may take all the collected data about operating characteristics plus one input from an end user: that end user may input the condition of the chambers as either 1) “ready for replacement/cleaning,” 2) “almost ready for replacement/cleaning,” or 3) “not ready for replacement/cleaning.” As the algorithm correlates the rest of the collected data with the input from the user, it can automatically arrive at the operating characteristics that indicate “almost ready for replacement/cleaning.”

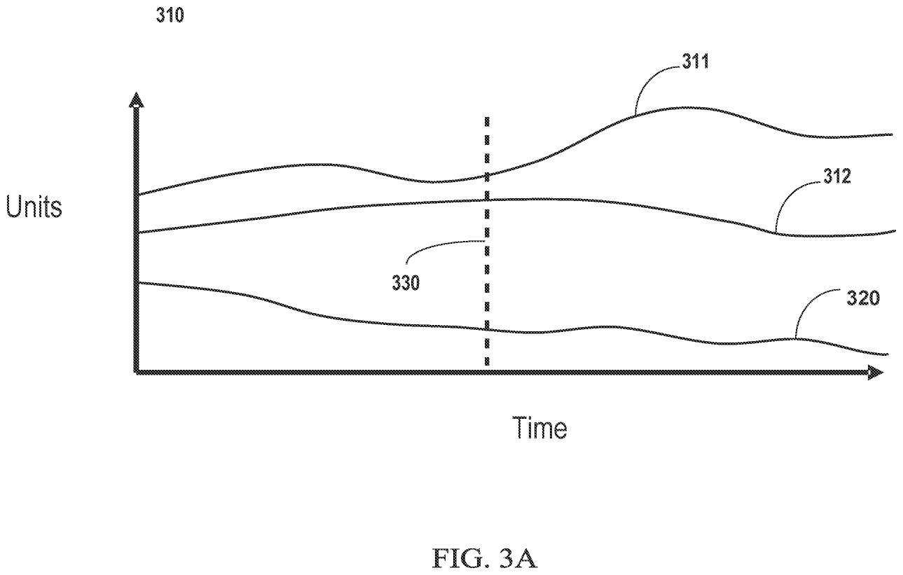

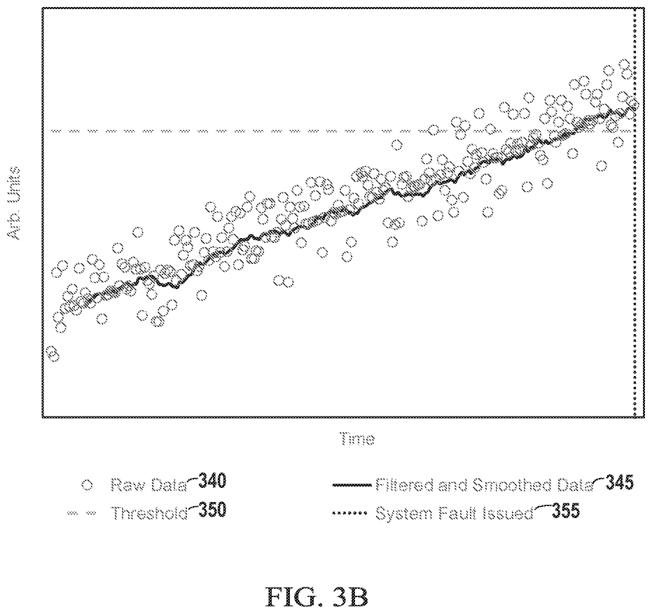

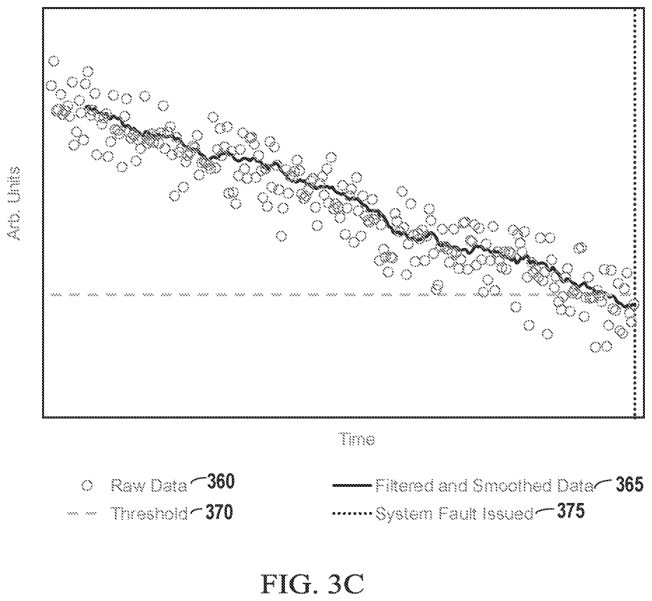

FIG. 3A depicts data that may be collected from an RPS and reported by an associated data acquisition system over time. Graph 310 shows measurements of N different parameters over time. These parameters may include DC voltage and current, AC voltage, current and phase, air flows and temperatures, water flows, temperatures and directions, and relative degree of inductive and capacitive coupling. Graph 310 shows Parameter 1 311, Parameter 2 312, and Parameter N 320, each varying over time. A particular “operating point” 330 represents the value of each of the operating parameters at a particular point in time. As shown, the various parameters may give measurements that vary independently of each other, and which do not visually convey any particular kind of correlation at the operating point 330. These parameters may be simply raw measured data, or they may be subjected to filtering and processing for the purpose of smoothing and removing artifacts. These parameters may also include estimates of indirect variables that may include but are not limited to chamber liner wall thickness, chamber liner surface condition, remaining chamber wall thickness, plasma characteristics (e.g. electron and ion density and impedance) and time remaining before preventative maintenance or repair are required.

FIGS. 3B and 3C show examples in which particular parameters, which may be subsets of all the measured and calculated parameters for a particular RPS, increase (FIG. 3B) and decrease (FIG. 3C) in value over time. The raw data points 340, 350 represent actual measured or calculated data points, and the filtered and smoothed data lines 345, 365 show values with various faulty or anomalous readings eliminated. Each of the graphs depict a system fault event 355, 375 near the end of the measured time period, as well as a threshold line 350, 370 set to a value at which multiple data point measurements indicate that a system fault event is impending. It is contemplated that increasing measures in FIG. 3B and decreasing measures in FIG. 3C may be detected in the same RPS unit for the same application; that is, they could represent any of parameters 1-N in FIG. 3A. The predictive analytics system of the present disclosure may detect correlations and create models from data comprising measurements and system fault events as shown in FIGS. 3B. and 3C.

As one example of a type of data point that may be indirectly measured, the relative degree of capacitive coupling may be determined by examining the impedance of the RPS chamber and plasma and comparing with empirical data or constitutive models which establish a threshold between the impedance characteristics of an inductively coupled plasma compared with a plasma generated by mixed coupling or capacitive coupling. Relative degree of capacitive coupling can be measured by a data acquisition system using data available from the specific RPS. Many types of measures of operating characteristics require filtering of raw measured data because some of the raw measurements are due to false indicators. For example, when an RPS turns on and off, several measurements may give temporary signals that are extremely high or extremely low, but these may not reflect actual conditions since they are artifacts of the transition between on and off states.

However, because the predictive data analytics system receives multiple pieces of data that correspond to the same time period before the system fault event, it can identify correlations between data that deviates greatly from its normal trajectory and data that does not. It can identify thresholds that might otherwise not appear to be indicative of the need for repair or service.

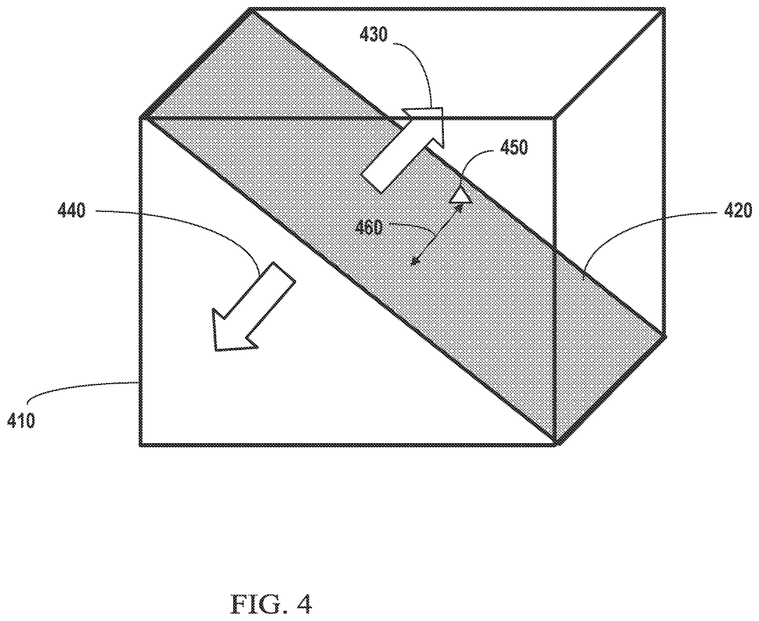

Turning to FIG. 4, an algorithm in the predictive analytics system may show that points in the N-dimensional space 410 within a certain distance from a hyperplane 420 are the most highly correlated with an impending need for repair, and predict the need with a particular degree of confidence within a defined future period of time. The N-dimensional space 410 comprises RPS data which may be used to assess the health of the RPS. These data may be processed for the purposes of smoothing, fitting, removing noise, and removing artifacts. As such events get recorded over time, the correlations between data may become more distinct, indicating the maximum instances of error rates that can occur before a system fault event occurs.

The N-dimensional space identified by the arrow 430 (space 430), graphically depicted “above” the hyperplane 420, represents a space in which an operating point is satisfactory, and the RPS is not in need of preventative maintenance. The N-dimensional space identified by the arrow 440 (space 440), graphically depicted “below” the hyperplane 420, represents a space in which an operating point is not satisfactory. At operating points within space 440, the RPS may require attention. A particular operating point 450 is shown in space 430. This particular operating point 450 may be the same as operating point 330 in FIG. 3, representing measurements of N parameters at a particular point in time. Operating point 450 is shown at a distance 460 from the hyperplane 420. This distance 460 may be used to set or define a threshold. Based on an algorithmic determination correlating maximum instances of error rates that can occur before a system fault occurs, a user, or the predictive analytics system itself, may set a threshold that alerts for a preventative maintenance to be performed the first time the distance from the operating point drops inside threshold. When a threshold is crossed an alert may be given, and action may be initiated, including possibly scheduling of maintenance by the predictive analytics system.

In the graph in FIG. 3A, it is difficult to assess exactly which pieces of data, of those illustrated, predict the need for maintenance or repair most strongly, because correlations are not visually apparent. When even more data points are collected, as they are in many embodiments, it quickly becomes impossible for a human analyst to assess which pieces of data correlate. The algorithms created by the predictive analytics system allow virtually every measurable characteristic to be assessed and correlated to system fault events. As a result, the thresholds for preventative maintenance alerts may be set at the most optimized level based on the most accurate data. In FIG. 4, it is possible that the threshold (i.e., the maximum distance from the hyperplane) may be set aggressively to maximize the time between preventative maintenance; for example, the predictive analytics system could calculate that preventative maintenance is recommended, but a repair is not required, when a threshold is crossed multiple times within a particular time interval which may be predetermined or determined by the predictive analytics system. The more operating characteristics can be collected, the more calculations may be performed by the predictive analytics system. Maximum optimization, however, may be achieved not only by taking in maximum different types of data, but also by taking it in repeatedly over the time domain.

FIG. 5 is an exemplary network architecture diagram showing how the predictive analytics system 500 of the present disclosure may be implemented. Several individual RPS units 501, 511, 521 are shown and labeled as “Type 1, Mfr. (manufacturer) A,” “Type 2, Mfr. A,” and “Type 3, Mfr. A,” respectively, to illustrate that the predictive analytics system of the present disclosure may be implemented with different models of RPS made by the same manufacturer. Additional RPS units 531 and 541 are labeled “Type 4, Mfr. B,” and “Type N, Mfr. N,” respectively, to illustrate that the same predictive analytics system may be implemented with any RPS from any manufacturer. The predictive analytics components, which, among other things, implement the algorithms to create predictions and preventative maintenance recommendations, are shown as “remote” predictive analytics component 505 and “local” predictive analytics component 515. Integration with either the remote or local predictive analytics components 505 and 515 are implemented through one or more data acquisition devices 502, 512, 522, 532, and 542. Although each RPS is depicted as connected to one data acquisition device, in embodiments, more than one RPS may be connected to a single data acquisition device.

The remote predictive analytics component 505 may be either remote in the sense that it is located at a robust server and takes in data from multiple RPS units. A remote predictive analytics component 505 may in fact be deployed “on-premise,”—e.g., at a semiconductor manufacturing plant which uses multiple RPS units. The remote predictive analytics component 505 may be on a LAN in such cases. In other embodiments, it may be at a remote cloud server on the internet, which may receive data from RPS units in many remote geographical locations, such as different manufacturing facility buildings, or different cities, states, and countries.

The local predictive analytics component 515, in contrast, may be run on a local PC or server, and may implement the predictive analytics algorithm and preventative maintenance warnings for one or just a few RPS units. It is contemplated that a local predictive analytics component 515 may be implemented in an external computing device, or a computing device integrated with the data acquisition device, such as one uniquely designed with an interface, processor, and memory compatible with the data acquisition device.

Each of the data acquisition devices 502, 512, 522, 532, and 542 may implement a particular protocol that defines what data is collected and/or measured from its associated RPS. Different RPS units may be equipped with different sensors and be otherwise configured differently from others, which may dictate the type of data that is possible to be measured. The different protocols 503, 513, 523, 533, 543 may themselves be changed according to different applications being run by their associated RPS units. That is, Type 1 Protocol 503 may have different iterations such as protocol “1A,” “1B,” “1C,” etc.

Once data is acquired by the data acquisition device under a particular protocol, the data may be transmitted to either a local database 550, a remote database 570, or both. Data acquisition devices 502, 512, 522, 532, and 542 are shown grouped and logically connected at 555 to remote database 570 to illustrate that data may be transmitted by each of these individual units to the remote database 570. Each individual data acquisition device may be in a different geographical location. The data, acquired via different protocols, may be integrated or assimilated through a unified protocol 548, which systematizes different types of acquired data so that it may be processed in a uniform manner in the databases 550, 570.

Referring to the remote predictive analytics component 505, it is contemplated that the database 570 may comprise many large data sets acquired and stored over time. These are depicted as big data component 572 and represents the voluminous raw data that may be analyzed to reveal patterns and used to implement the other aspects of the predictive analytics component. This big data component 572 may be organized and managed through the database/data management component 571, which may be implemented through commercially available tools, including relational database management systems such as SQL.

The remote database 570 is configured to serve data to the analytics engine 580. The analytics engine 580 may be executed on a server and may comprise several applications. These applications may include a data science component 584 and a data engineering component 585. Each of these may comprise tools and interfaces for data scientists and data engineers to manipulate data, provide inputs such as thresholds, and assist in creating algorithms. The analytics engine 580 may also comprise an applications development component 581, which may create specific preventative maintenance algorithms for particular RPS units and applications. Once developed, the algorithms for the specific applications may be deployed with the local predictive analytics component 515 or even the individual RPS units that are to be used for those applications. Those deployed RPS units may run independently and not require connection to a local or remote predictive analytics component, having local algorithms implemented directly within the RPS unit. In embodiments, the local predictive analytics component 515 may not be within the RPS unit itself, but the RPS unit and connected local predictive analytics component 515 may run independently, without any connection to the remote predictive analytics component 505. The model development component 582 may create models of likelihoods of events occurring with mathematical probabilities with certain periods of time based on analysis of the big data. It is contemplated that the applications development component 581 and the model development component 582 may be implemented through machine learning programs.

Because of the large data sets that may be used to create the applications and models, data visualization is beneficial for providing usable insights to users such as data scientists and data engineers. The analytics engine 580 may therefore comprise a big data visualization component 583, which may be implemented as a graphical user interface with graphs, charts, and other visualization tools.

The local predictive analytics engine 560 may comprise many similar components and functions as the remote predictive analytics engine 580, but may be implemented on a smaller scale and designed for an end user of the one or more attached RPS. As shown, an applications configuration component 561 of a local analytics engine 560 may use the data collected in local database 550 to create and/or operate predictive maintenance schedules for the connected RPS. The applications configuration component 561 may be used to implement operations initially created on the remote predictive analytics component 515, and may be used to adjust local configurations and set local thresholds. The local data visualization component 562 may show the user the actual alerts 563, analytics 564, and KPI (key performance indicators) 565 (e.g., on a graphical user interface).

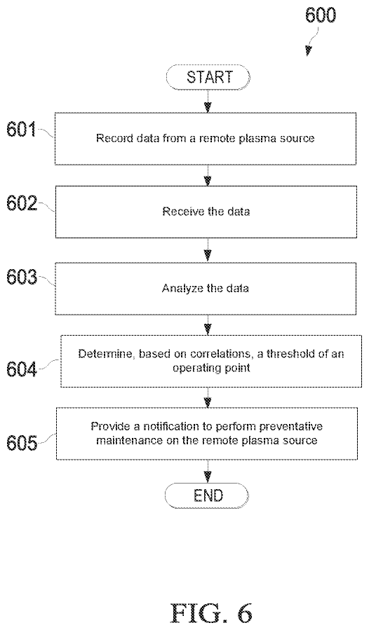

FIG. 6 is a flowchart 600 showing method steps that may be performed to implement embodiments of the disclosure. Method steps can be interchanged without departing from the scope of the invention. The method may first comprise, at step 601 recording data from a remote plasma source. The data may comprise measurements of one or more operating characteristics of the remote plasma source over a period of time and a plurality of indications of system fault event. The method may then comprise, at step 602, receiving the data, and at step 603, analyzing the data. The method may comprise, at step 604, determining, based on correlations between the measurements of the one or more operating characteristics and the plurality of system fault events, a threshold of an operating point. The operating point may comprise the measurements of the one or more operating characteristics at a particular time. The threshold may signify a pending system fault event is probable to a defined degree of confidence within a specified window of time. The method may then comprise, at step 605, providing a notification to perform preventative maintenance on the remote plasma source.

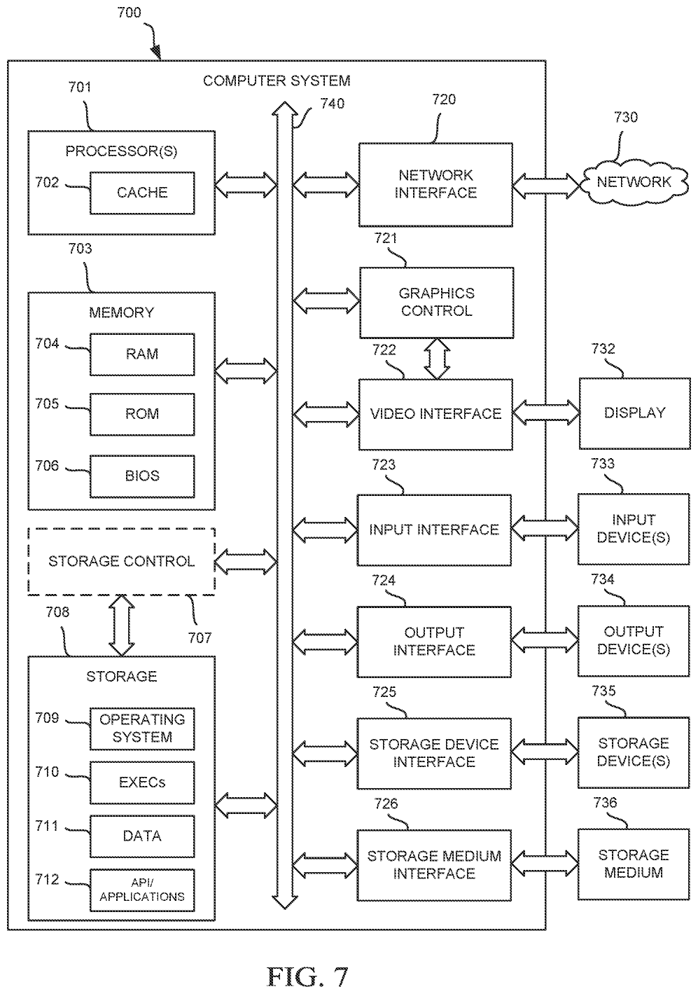

The systems and methods described herein can be implemented in a computer system in addition to the specific physical devices described herein. FIG. 7 shows a diagrammatic representation of one embodiment of a computer system 700 within which a set of instructions can execute for causing a device to perform or execute any one or more of the aspects and/or methodologies of the present disclosure. Local computer 560 and remote server 580 in FIG. 5 are two implementations of the computer system 700. The components in FIG. 7 are examples only and do not limit the scope of use or functionality of any hardware, software, firmware, embedded logic component, or a combination of two or more such components implementing particular embodiments of this disclosure. Some or all of the illustrated components can be part of the computer system 700. For instance, the computer system 700 can be a general purpose computer (e.g., a laptop computer) or an embedded logic device (e.g., an FPGA), to name just two non-limiting examples.

Computer system 700 includes at least a processor 701 such as a central processing unit (CPU), graphics processing unit (GPU) or an FPGA to name three non-limiting examples. The computer system 700 may also comprise a memory 703 and a storage 708, both communicating with each other, and with other components, via a bus 740. The bus 740 may also link a display 732, one or more input devices 733 (which may, for example, include a keypad, a keyboard, a mouse, a stylus, etc.), one or more output devices 734, one or more storage devices 735, and various non-transitory, tangible computer-readable storage media 736 with each other and with one or more of the processor 701, the memory 703, and the storage 708. All of these elements may interface directly or via one or more interfaces or adaptors to the bus 740. For instance, the various non-transitory, tangible computer-readable storage media 736 can interface with the bus 740 via storage medium interface 726. Computer system 700 may have any suitable physical form, including but not limited to one or more integrated circuits (ICs), printed circuit boards (PCBs), mobile handheld devices (such as mobile telephones or PDAs), laptop or notebook computers, distributed computer systems, computing grids, or servers.

Processor(s) 701 (or central processing unit(s) (CPU(s))) optionally contains a cache memory unit 702 for temporary local storage of instructions, data, or computer addresses. Processor(s) 701 are configured to assist in execution of computer-readable instructions stored on at least one non-transitory, tangible computer-readable storage medium. Processor(s) 701 may include one or more graphics processing units (GPU(s)). In some embodiments, the GPU may be used to execute machine learning AI (artificial intelligence) programs. Computer system 700 may provide functionality as a result of the processor(s) 701 executing software embodied in one or more non-transitory, tangible computer-readable storage media, such as memory 703, storage 708, storage devices 735, and/or storage medium 736 (e.g., read only memory (ROM)). For instance, the method 600 in FIG. 6 may be embodied in one or more non-transitory, tangible computer-readable storage media. The non-transitory, tangible computer-readable storage media may store software that implements particular embodiments, such as the method 600 and processor(s) 701 may execute the software. Memory 703 may read the software from one or more other non-transitory, tangible computer-readable storage media (such as mass storage device(s) 735, 736) or from one or more other sources through a suitable interface, such as network interface 720. The software may cause processor(s) 701 to carry out one or more processes or one or more steps of one or more processes described or illustrated herein. Carrying out such processes or steps may include defining data structures stored in memory 703 and modifying the data structures as directed by the software. In some embodiments, an FPGA can store instructions for carrying out functionality as described in this disclosure (e.g., the method 600). In other embodiments, firmware includes instructions for carrying out functionality as described in this disclosure (e.g., the method 600)

The memory 703 may include various components (e.g., non-transitory, tangible computer-readable storage media) including, but not limited to, a random access memory component (e.g., RAM 704) (e.g., a static RAM “SRAM”, a dynamic RAM “DRAM, etc.), a read-only component (e.g., ROM 705), and any combinations thereof. ROM 705 may act to communicate data and instructions unidirectionally to processor(s) 701, and RAM 704 may act to communicate data and instructions bidirectionally with processor(s) 701. ROM 705 and RAM 704 may include any suitable non-transitory, tangible computer-readable storage media described below. In some instances, ROM 705 and RAM 704 include non-transitory, tangible computer-readable storage media for carrying out the method 600. In one example, a basic input/output system 706 (BIOS), including basic routines that help to transfer information between elements within computer system 700, such as during start-up, may be stored in the memory 703.

Fixed storage 708 is connected bidirectionally to processor(s) 701, optionally through storage control unit 707. Fixed storage 708 provides additional data storage capacity and may also include any suitable non-transitory, tangible computer-readable media described herein. Storage 708 may be used to store operating system 709, EXECs 710 (executables), data 711, API applications 712 (application programs), and the like. For instance, the storage 708 could be implemented for storage of data as described in FIG. 5. Often, although not always, storage 708 is a secondary storage medium (such as a hard disk) that is slower than primary storage (e.g., memory 703). Storage 708 can also include an optical disk drive, a solid-state memory device (e.g., flash-based systems), or a combination of any of the above. Information in storage 708 may, in appropriate cases, be incorporated as virtual memory in memory 703.

In one example, storage device(s) 735 may be removably interfaced with computer system 700 (e.g., via an external port connector (not shown)) via a storage device interface 725. Particularly, storage device(s) 735 and an associated machine-readable medium may provide nonvolatile and/or volatile storage of machine-readable instructions, data structures, program modules, and/or other data for the computer system 700. In one example, software may reside, completely or partially, within a machine-readable medium on storage device(s) 735. In another example, software may reside, completely or partially, within processor(s) 701.

Bus 740 connects a wide variety of subsystems. Herein, reference to a bus may encompass one or more digital signal lines serving a common function, where appropriate. Bus 740 may be any of several types of bus structures including, but not limited to, a memory bus, a memory controller, a peripheral bus, a local bus, and any combinations thereof, using any of a variety of bus architectures. As an example and not by way of limitation, such architectures include an Industry Standard Architecture (ISA) bus, an Enhanced ISA (EISA) bus, a Micro Channel Architecture (MCA) bus, a Video Electronics Standards Association local bus (VLB), a Peripheral Component Interconnect (PCI) bus, a PCI-Express (PCI-X) bus, an Accelerated Graphics Port (AGP) bus, HyperTransport (HTX) bus, serial advanced technology attachment (SATA) bus, and any combinations thereof.

Computer system 700 may also include an input device 733. In one example, a user of computer system 700 may enter commands and/or other information into computer system 700 via input device(s) 733. Examples of an input device(s) 733 include, but are not limited to, an alpha-numeric input device (e.g., a keyboard), a pointing device (e.g., a mouse or touchpad), a touchpad, a joystick, a gamepad, an audio input device (e.g., a microphone, a voice response system, etc.), an optical scanner, a video or still image capture device (e.g., a camera), and any combinations thereof. Input device(s) 733 may be interfaced to bus 740 via any of a variety of input interfaces 723 (e.g., input interface 723) including, but not limited to, serial, parallel, game port, USB, FIREWIRE, THUNDERBOLT, or any combination of the above.

In particular embodiments, when computer system 700 is connected to network 730 computer system 700 may communicate with other devices, such as mobile devices and enterprise systems, connected to network 730. Communications to and from computer system 700 may be sent through network interface 720. For example, network interface 720 may receive incoming communications (such as requests or responses from other devices) in the form of one or more packets (such as Internet Protocol (IP) packets) from network 730, and computer system 700 may store the incoming communications in memory 703 for processing. Computer system 700 may similarly store outgoing communications (such as requests or responses to other devices) in the form of one or more packets in memory 703 and communicated to network 730 from network interface 720. Processor(s) 701 may access these communication packets stored in memory 703 for processing.

Examples of the network interface 720 include, but are not limited to, a network interface card, a modem, and any combination thereof. Examples of a network 730 or network segment 730 include, but are not limited to, a wide area network (WAN) (e.g., the Internet, an enterprise network), a local area network (LAN) (e.g., a network associated with an office, a building, a campus or other relatively small geographic space), a telephone network, a direct connection between two computing devices, and any combinations thereof. A network, such as network 730, may employ a wired and/or a wireless mode of communication. In general, any network topology may be used.

Information and data can be displayed through a display 732. Examples of a display 732 include, but are not limited to, a liquid crystal display (LCD), an organic liquid crystal display (OLED), a cathode ray tube (CRT), a plasma display, and any combinations thereof. The display 732 can interface to the processor(s) 701, memory 703, and fixed storage 708, as well as other devices, such as input device(s) 733, via the bus 740. The display 732 is linked to the bus 740 via a video interface 722, and transport of data between the display 732 and the bus 740 can be controlled via the graphics control 721.

In addition to a display 732, computer system 700 may include one or more other peripheral output devices 734 including, but not limited to, an audio speaker, a printer, and any combinations thereof. Such peripheral output devices may be connected to the bus 740 via an output interface 724. Examples of an output interface 724 include, but are not limited to, a serial port, a parallel connection, a USB port, a FIREWIRE port, a THUNDERBOLT port, and any combinations thereof.

In addition, or as an alternative, computer system 700 may provide functionality as a result of logic hardwired or otherwise embodied in a circuit, which may operate in place of or together with software to execute one or more processes or one or more steps of one or more processes described or illustrated herein. Reference to software in this disclosure may encompass logic, and reference to logic may encompass software. Moreover, reference to a non-transitory, tangible computer-readable medium may encompass a circuit (such as an IC) storing software for execution, a circuit embodying logic for execution, or both, where appropriate. The present disclosure encompasses any suitable combination of hardware, software, or both.

Those of skill in the art will understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Within this specification, the same reference characters are used to refer to terminals, signal lines, wires, etc. and their corresponding signals. In this regard, the terms “signal,” “wire,” “connection,” “terminal,” and “pin” may be used interchangeably, from time-to-time, within the this specification. It also should be appreciated that the terms “signal,” “wire,” or the like can represent one or more signals, e.g., the conveyance of a single bit through a single wire or the conveyance of multiple parallel bits through multiple parallel wires. Further, each wire or signal may represent bi-directional communication between two, or more, components connected by a signal or wire, as the case may be.

Those of skill will further appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the embodiments disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The steps of a method or algorithm described in connection with the embodiments disclosed herein (e.g., the method 600) may be embodied directly in hardware, in a software module executed by a processor, a software module implemented as digital logic devices, or in a combination of these. A software module may reside in RAM memory, flash memory, ROM memory, EPROM memory, EEPROM memory, registers, hard disk, a removable disk, a CD-ROM, or any other form of non-transitory, tangible computer-readable storage medium known in the art. An exemplary non-transitory, tangible computer-readable storage medium is coupled to the processor such that the processor can read information from, and write information to, the non-transitory, tangible computer-readable storage medium. In the alternative, the non-transitory, tangible computer-readable storage medium may be integral to the processor. The processor and the non-transitory, tangible computer-readable storage medium may reside in an ASIC. The ASIC may reside in a user terminal. In the alternative, the processor and the non-transitory, tangible computer-readable storage medium may reside as discrete components in a user terminal. In some embodiments, a software module may be implemented as digital logic components such as those in an FPGA once programmed with the software module.

The previous description of the disclosed embodiments is provided to enable any person skilled in the art to make or use the present disclosure. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

1. A system comprising:
a remote plasma source;
a data acquisition device connected to the remote plasma source and configured to record data indicative of operating characteristics of the remote plasma source; and
a machine learning component to:
determine a correlation between the recorded data and user-input data, the user-input data identifying a condition of the remote plasma source; and
provide a notification to perform preventative maintenance based upon the correlation.

2. The system of claim 1, wherein the data acquisition device is configured to record a plurality of indications of system fault events and the machine learning component is configured to determine a correlation between the recorded data and the plurality of indications of system fault events to provide the notification to perform preventative maintenance.

3. The system of claim 1 wherein the machine learning component is configured to utilize one or more indirect measurements as the recorded data.

4. The system of claim 3, wherein the one or more indirect measurements comprises one or more of:
a component of a plasma and chamber impedance; and
a characteristic of a wall of a chamber of the remote plasma source.

5. The system of claim 1, wherein the operating characteristics comprise one or more of current, voltage, temperature, and an impedance.

6. The system of claim 1, wherein the machine learning component resides on a server that to remote from the remote plasma source.

7. The system of claim 1, further comprising:
a plurality of additional remote plasma sources; and
a plurality of additional data acquisition devices, and wherein
the data further comprises:
additional measurements from each of the plurality of additional remote plasma sources; and
additional indications of system faults from each of the remote plasma sources.

8. The system of claim 7, wherein at least some of the plurality of additional remote plasma sources are in different geographical locations.

9. The system of claim 1, wherein the machine learning component is configured to automatically develop an algorithm to set a threshold, a pending system fault event is probable to a defined degree of confidence within a specified window of time.

10. A method for maintaining a remote plasma source, the method comprising:
recording data from the remote plasma source, the data comprising measurements of one or more operating characteristics of the remote plasma source over a period of time;
determining, with a machine learning component, correlations between the measurements of the one or more operating characteristics and a user-input data identifying a condition of the remote plasma source;
establishing, a threshold of an operating point based upon the correlations between the measurements of the one or more operating characteristics and the user-input data, the operating point comprising the measurements of the one or more operating characteristics at a particular time; and
providing a notification to perform preventative maintenance on the remote plasma source when the threshold is met.

11. The method of claim 10 wherein the determining comprises determining, with the machine learning component, correlations between the measurements of the one or more operating characteristics, the user-input data, and a plurality of indications of system fault events.

12. The method of claim 11, wherein the threshold signifies a pending system fault event is probable to a defined degree of confidence within a specified window of time.

13. The method of claim 12, further comprising:
calculating one or more indirect measurements of the one or more operating characteristics, wherein the determining is based on one or more calculated indirect measurements.

14. The method of claim 13, wherein the one or more indirect measurements comprises one or more of:
a component of a plasma and chamber impedance; and
a characteristic of a chamber wall.

15. The method of claim 12, wherein the one or more operating characteristics comprise one or more of a current, a voltage, a temperature, and an impedance.

16. A non-transitory, tangible computer readable storage medium, encoded with processor readable instructions, the instructions comprising instructions for:
recording data from a remote plasma source, the data comprising measurements of one or more operating characteristics of the remote plasma source over a period of time;
determining, with a machine learning component, correlations between the measurements of the one or more operating characteristics and a user-input data identifying a condition of the remote plasma source;
establishing, a threshold of an operating point based upon the correlations between the measurements of the one or more operating characteristics and the user-input data, the operating point comprising the measurements of the one or more operating characteristics at a particular time; and
providing a notification to perform preventative maintenance on the remote plasma source when the threshold is met.

17. The non-transitory, tangible computer readable storage medium of claim 16, wherein the one or more operating characteristics comprise one or more of a current, a voltage, a temperature, and an impedance.

18. The non-transitory, tangible processor readable storage medium of claim 16, the instructions further comprising instructions for:
transmitting the data from the remote plasma source to a remote server, wherein the determining is performed at the remote server.

19. The non-transitory, tangible computer readable storage medium of claim 16, the instructions further comprising instructions for:
recording data from a plurality of additional remote plasma sources; and
acquiring data from a plurality of additional data acquisition devices, and wherein the data further comprises:
additional measurements from each of the plurality of additional remote plasma sources; and
additional indications of system faults from each of the remote plasma sources.

20. The non-transitory, tangible computer readable storage medium of claim 16, the instructions further comprising instructions for:
automatically developing, by the machine learning component, an algorithm to set the threshold.
